(19) United States
(12) Patent Application Publication
(10) Pub. No.: US 2026/0177602 A1
(43) Pub. Date: Jun. 25, 2026

(54) ACTIVE DETECTION APPARATUS AND METHOD FOR DISCHARGE DEFECT OF LINE INSULATOR

(71) Applicants: WUXI POWER SUPPLY BRANCH OF STATE GRID JIANGSU ELECTRIC POWER CO., LTD., Wuxi (CN); XI'AN JIAOTONG UNIVERSITY, Xi'an (CN)

(72) Inventors: Jin MIAO, Wuxi (CN); Zhiwei ZHANG, Nanjing (CN); Jingjing CHEN, Wuxi (CN); Gang WU, Wuxi (CN); Huimin YU, Wuxi (CN); Junfeng WU, Wuxi (CN); Ming REN, Xi'an (CN)

(21) Appl. No.: 19/257,922

(22) Filed: Jul. 2, 2025

Related U.S. Application Data
(63) Continuation of application No. PCT/CN2025/094162, filed on May 12, 2025.

(30) Foreign Application Priority Data
Dec. 24, 2024 (CN) 202411915858.0

(51) Int. Cl. G01R 31/12

(52) U.S. Cl. CPC G01R 31/1218

(57) ABSTRACT

An active detection apparatus for a discharge defect of a line insulator includes a repetition frequency x-ray pulse light source, a solar-blind ultraviolet photosensitive detection unit, a switching quantity counter, an ultrasonic distance measurement unit, an information calculation unit and an execution control unit. The repetition frequency x-ray pulse light source is configured to generate an x-ray light pulse with a repetition frequency. The ultrasonic distance measurement unit is configured to obtain a distance between the solar-blind ultraviolet photosensitive detection unit and a measured insulator. The solar-blind ultraviolet photosensitive detection unit is configured to detect an insulation discharge ultraviolet photon generated after x-ray excitation. The switching quantity counter is configured to count a high-level pulse sequence output by the solar-blind ultraviolet photosensitive detection unit. The information calculation unit is configured to process information output by the switching quantity counter and provide a state determination result of the measured insulator.

### CROSS-REFERENCES TO RELATED APPLICATIONS

This is a continuation application of International Patent Application No. PCT/CN2025/094162, filed May 12, 2025, which claims priority to Chinese Patent Application No. 202411915858.0, filed with the China National Intellectual Property Administration (CNIPA) on Dec. 24, 2024, the disclosures of which are incorporated herein by reference in their entireties.

### TECHNICAL FIELD

The present application relates to the technical field of transmission line insulation detection, for example, an active detection apparatus for a discharge defect of a line insulator and an active detection method for a discharge defect of a line insulator.

### BACKGROUND

The sudden short circuit in the power transmission line poses a significant threat to the safe operation of the power grid, and contamination, aging, or a defect of an insulator are important causes of such sudden short circuit faults in the line. The insulator performs dual functions of mechanical support and electrical insulation in the line, and various defects such as dirt accumulation, aging, cracking, and the like are inevitably generated when the insulator runs in complicated atmospheric environments such as ultraviolet irradiation, high humidity, dust, salt mist, rain, snow and the like. Such an insulation defect, once formed, may accelerate the insulation failure process. Generally, when the aging or the defect reaches a certain degree, an abnormal discharge phenomena occurs under the voltage, as a result, the insulation defect may be found by means of the discharge detection technology. However, the partial discharge caused by most of the defects is non-continuous and unstable but exhibits latent, sporadic and random properties, so that even the discharge phenomenon under the operating voltage is not obvious. In recent years, many insulator flashover accidents without obvious pre-discharge symptoms before faults have occurred; therefore, there is an urgent need to explore a new sensitive and efficient detection method for a defect of an insulator.

The conventional detection methods for the defect of the insulator mainly include ultrasonic detection, infrared thermal imaging, and solar-blind ultraviolet imaging. In the ultrasonic detection, the insulator discharges to cause the rapid thermal expansion and contraction of the local medium, so that the mechanical wave is transmitted in different media, and the insulator discharge ultrasonic signal may be obtained through the ultrasonic coupling sensor. In the infrared thermal imaging, when the discharge energy is strong enough and the duration is long enough, the discharge may cause local heating, and an infrared thermal imager may be used for detecting the abnormal temperature rise to indirectly reflect the discharge condition. In the solar-blind ultraviolet imaging, the surface discharge of the insulator may cause the light emission of the ultraviolet band, the photon imaging detection is performed by adopting the solar-blind waveband, so that the discharge signal can be effectively detected while avoiding sunlight interference. However, the main problems of the above detection methods are as follows. \textcircled{1} The operating voltage of the insulator is generally far lower than the designed field intensity, and the critical discharge electric field in the insulation defect is relatively high, so that the stable discharge is difficult to excite under the limited electric field. \textcircled{2} The partial discharge caused by the insulation defect under the limited voltage level often exhibits a strong sporadic property, and the amplitude value of the partial discharge is lower than the detection threshold. \textcircled{3} The conventional detection means is a passive detection, and the discharge caused by the defect needs to wait for specific conditions, such as an increase of defect scale, high-humidity environment, material aging, and the like, so that the discharge signal is difficult to be captured within the limited detection time.

### SUMMARY

The present application provides an active detection apparatus for a discharge defect of a line insulator and an active detection method for a discharge defect of a line insulator, to provide an active discharge detection technology for rapidly checking and determining the defect of the line insulator.

A first aspect of the present application provides an active detection apparatus for a discharge defect of a line insulator. The apparatus includes: a repetition frequency x-ray pulse light source, a solar-blind ultraviolet photosensitive detection unit, a switching quantity counter, an ultrasonic distance measurement unit, an information calculation unit and an execution control unit. The execution control unit is connected to each of the repetition frequency x-ray pulse light source, the solar-blind ultraviolet photosensitive detection unit, the switching quantity counter, the ultrasonic distance measurement unit and the information calculation unit, and the execution control unit is configured to control at least one of an operation start and end and an output parameter of the repetition frequency x-ray pulse light source, at least one of an operation start and end and an output parameter of the solar-blind ultraviolet photosensitive detection unit, at least one of an operation start and end and an output parameter of the switching quantity counter, at least one of an operation start and end and an output parameter of the ultrasonic distance measurement unit, and at least one of an operation start and end and an output parameter of the information calculation unit. The repetition frequency x-ray pulse light source is configured to generate an x-ray light pulse with a repetition frequency, the ultrasonic distance measurement unit is configured to obtain a distance between the solar-blind ultraviolet photosensitive detection unit and a measured insulator, the solar-blind ultraviolet photosensitive detection unit, the switching quantity counter and the information calculation unit are connected in sequence, the solar-blind ultraviolet photosensitive detection unit is configured to detect an insulation discharge ultraviolet photon generated after x-ray excitation, the switching quantity counter is configured to count a high-level pulse sequence output by the solar-blind ultraviolet photosensitive detection unit, and the information calculation unit is configured to process information output by the switching quantity counter and provide a state determination result of the measured insulator.

In some embodiments, an irradiation angle of the repetition frequency x-ray pulse light source is not less than 15°, a central wavelength range is 0.5 nm to 10 nm, a controllable dose range of a single pulse x-ray is 5 μSv to 15 μSv, a controllable range of pulse half-peak time is 0.5 us to 5 μs, and a light pulse repetition frequency is adjustable within 10 Hz to 50 Hz.

In some embodiments, a response wavelength range of the solar-blind ultraviolet photosensitive detection unit is 240 nm to 280 nm, light quantum efficiency within a solar-blind waveband is not less than 15%, light pulse response time is less than 200 ns, an effective detection angle θ at least ranges from −30° to +30°, and a photoelectric gain is not less than 60 dB.

In some embodiments, the solar-blind ultraviolet photosensitive detection unit is configured to output a high-level square wave pulse signal after receiving a photon signal, and a pulse width is less than 200 ns.

In some embodiments, the execution control unit is configured to control the operation start and end and the output parameter of the repetition frequency x-ray pulse light source, the operation start and end of the solar-blind ultraviolet photosensitive detection unit, the operation start and end and the output parameter of the switching quantity counter, and the operation start and end of the information calculation unit.

A second aspect of the present application provides an active detection method for a discharge defect of a line insulator, applied to the active detection apparatus for the discharge defect of the line insulator described in the first aspect of the present application. The method includes that: activating, by the execution control unit, the solar-blind ultraviolet photosensitive detection unit, and measuring a background light pulse when no x-ray is applied, to obtain an average discharge frequency, recorded as n0, within T time; setting, by the execution control unit, a single pulse x-ray controllable dose R of the repetition frequency x-ray pulse light source; activating, by the execution control unit, the repetition frequency x-ray pulse light source to irradiate a target region of a measured line insulator; immediately activating, by the execution control unit, the solar-blind ultraviolet photosensitive detection unit after a pulse output of the repetition frequency x-ray pulse light source is finished, where a detection frequency is kept consistent with an x-ray pulse repetition frequency; activating, by the execution control unit, the switching quantity counter, and keeping a working time of the switching quantity counter consistent with a working time of the repetition frequency x-ray pulse light source, to obtain a discharge light pulse frequency, recorded as n, in an x-ray pulse interval time Δt; activating, by the execution control unit, the ultrasonic distance measurement unit, and keeping a working time of the ultrasonic distance measurement unit consistent with the working time of the repetition frequency x-ray pulse light source, to obtain an ultrasonic distance measurement value L in the x-ray pulse interval time Δt; and activating, by the execution control unit, the information calculation unit, keeping a working time of the information calculation unit consistent with the working time of the repetition frequency x-ray pulse light source, calculating a discharge photon excitation intensity S at a t moment, and providing, by the information calculation unit, a graded evaluation result according to a calculation result of the discharge photon excitation intensity S, to obtain a discharge state of the measured line insulator.

In some embodiments, when the repetition frequency x-ray pulse light source is activated by the execution control unit to irradiate the target region of the measured line insulator, an x-ray cumulative dose is not higher than 10 mSv.

In some embodiments, the discharge photon excitation intensity S at the t moment is calculated through the following formula:

$$S ( t ) = \frac{R \cdot [ n ( t ) - {n}_{0} ]}{tan θ \cdot L ( t )}$$

in the formula, n(t) is an x-ray discharge light pulse frequency at the t moment, no is the average discharge frequency of the background light pulse within the T time when no x-ray is applied, L(t) is an ultrasonic distance measurement value at the t moment, R is the single pulse x-ray controllable dose of the repetition frequency x-ray pulse light source, and θ is an effective detection angle of the solar-blind ultraviolet photosensitive detection unit.

In some embodiments, the graded evaluation result provided by the information calculation unit includes normal, concern, tracking, early warning and alarm.

In some embodiments, providing, by the information calculation unit, the graded evaluation result according to the calculation result of the discharge photon excitation intensity S includes: setting an effective check value m; inputting data S(tᵢ), and outputting, in response to determining that S(tᵢ)≤0, the graded evaluation result as normal; checking, in response to determining that S(tᵢ)>0, whether the data S(tᵢ) is valid, confirming, in response to determining that |S(tᵢ)−S(tᵢ₋₁)|≤m, that the data S(tᵢ) is valid for the next evaluation process; and outputting, in response to determining that S(tᵢ)≤a1, the graded evaluation result as concern; outputting, in response to determining that a1<S(tᵢ)≤a2, the graded evaluation result as tracking; outputting, in response to determining that a2<S(tᵢ)≤a3, the graded evaluation result as early warning; and outputting, in response to determining that a3<S(tᵢ), the graded evaluation result as alarm. Where i is a positive integer, each of a1, a2 and a3 is a state threshold.

### BRIEF DESCRIPTION OF DRAWINGS

FIG. 1 is a schematic diagram of a hardware structure of a solar-blind ultraviolet photon detection apparatus based on an X-ray source;

FIG. 2 is a startup sequence of a solar-blind ultraviolet photon detection apparatus based on an X-ray source during operation;

FIG. 3 is a schematic flowchart of a graded evaluation logic based on a discharge photon excitation intensity S; and

FIG. 4 is a schematic diagram of a result of a graded evaluation logic based on a discharge photon excitation intensity S in some embodiments.

### DETAILED DESCRIPTION

Embodiments of the present application will be described below in conjunction with the drawings in the embodiments of the present application. The described embodiments are some embodiments related to the present application. All other embodiments obtained by those of ordinary skill in the art based on the spirits of the present application without requiring creative efforts shall all fall within the scope of protection of the present application.

Theoretically speaking, a necessary condition for the discharge caused by an insulation defect is that the external applied field strength is higher than the critical discharge field strength of the defect. Therefore, the micro defect does not necessarily accompany the discharge phenomenon, as operational years increase, the potential defect may rapidly develop into a sudden insulation fault. Under the irradiation of short-wave exogenous sources such as an x-ray, the insulation defect may generate a stable discharge under the relatively low electric field, thereby reducing the threshold of the partial discharge field, and facilitating the quick and effective detection of the defect. Therefore, the present application provides an insulator discharge defect detection technology excited by an active light source, where the active light source is suitable for being carried by an unmanned aerial vehicle, thereby enabling the active, fast and accurate detection of a defect of a line insulator.

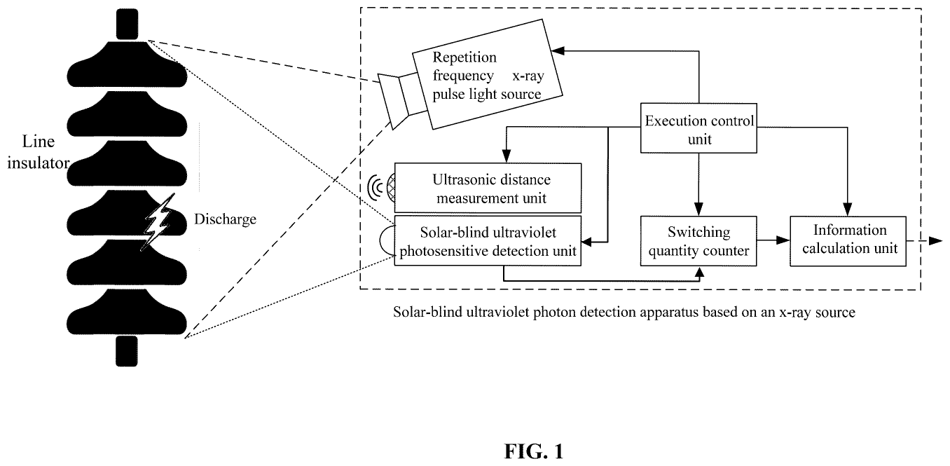

The present application provides an active detection apparatus for a discharge defect of a line insulator in an embodiment 1. As shown in FIG. 1, the hardware structure of the apparatus is a solar-blind ultraviolet photon detection apparatus based on an x-ray source. The active detection apparatus includes a repetition frequency x-ray pulse light source, a solar-blind ultraviolet photosensitive detection unit, a switching quantity counter, an ultrasonic distance measurement unit, an information calculation unit and an execution control unit. The execution control unit is connected to each of the repetition frequency x-ray pulse light source, the solar-blind ultraviolet photosensitive detection unit, the switching quantity counter, the ultrasonic distance measurement unit and the information calculation unit. The solar-blind ultraviolet photosensitive detection unit, the switching quantity counter and the information calculation unit are connected in sequence. The execution control unit is configured to control the repetition frequency x-ray pulse light source to irradiate a detected insulator. The solar-blind photosensitive sensor detects a discharge photon signal and transmits the discharge photon signal to the switching quantity counter in an interval period after the repetition frequency pulse light source irradiates. The information calculation unit is configured to evaluate the strength of the discharge signal through distance information obtained by the ultrasonic distance measurement unit and a photon counting result obtained by the switching quantity counter.

In some embodiments, the apparatus is a functional load for power line inspection of the unmanned aerial vehicle and is used for checking and determining defects in various types of line insulators and detecting abnormal discharge online.

In some embodiments, the repetition frequency x-ray pulse light source is configured to generate an x-ray light pulse with a repetition frequency. Exemplarily, an irradiation angle of the repetition frequency x-ray pulse light source is not less than 15°, a central wavelength range is in a soft x-ray range (0.5 nm to 10 nm), a controllable dose range of a single pulse x-ray is 5 μSv to 15 μSv, a controllable range of pulse half-peak time is 0.5 μs to 5 μs, and a light pulse repetition frequency is adjustable within 10 Hz to 50 Hz. Both the optical power output peak and the optical pulse half-peak time of the above-described pulse light source are adjusted by the execution control unit.

In some embodiments, the solar-blind ultraviolet photosensitive detection unit is configured to detect an insulation discharge ultraviolet photon generated after x-ray excitation. A response wavelength range of the solar-blind ultraviolet photosensitive detection unit is an ultraviolet solar-blind waveband (240 nm to 280 nm). Light quantum efficiency in the solar-blind waveband is not less than 15%. Light pulse response time is less than 200 ns. An effective detection angle θ at least ranges from −30° to +30°, the detection angle is symmetrical with the horizontal line as the axis of symmetry. A photoelectric gain is not less than 60 dB. After the photon signal is received, a high-level square wave pulse signal may be output, where the pulse width is less than 200 ns.

In some embodiments, the switching quantity counter is configured to count a high-level pulse sequence output by the solar-blind ultraviolet photosensitive detection unit to output the number of light pulses, recorded as n, in an x-ray pulse interval time Δt.

In some embodiments, the ultrasonic distance measurement unit is configured to obtain a distance between the solar-blind ultraviolet photosensitive detection unit and a detection object to output an ultrasonic distance measurement value L, recorded as L, in the x-ray pulse interval time Δt.

In some embodiments, the information calculation unit is configured to process information output by the switching quantity counter, calculate a discharge photon excitation intensity according to the calculation steps of the discharge photon excitation intensity S, and provide a state determination result. Exemplarily, the state determination result includes normal, concern, tracking, early warning and alarm.

In some embodiments, the execution control unit is configured to control the operation start and end and the output parameter of the repetition frequency x-ray pulse light source, the operation start and end of the solar-blind ultraviolet photosensitive detection unit, the operation start and end and the output parameter of the switching quantity counter, and the operation start and end of the information calculation unit.

In some embodiments, the execution command of the execution control unit may be controlled and issued by the host computer.

The present application provides an active detection method for a discharge defect of a line insulator in an embodiment 2, and the active detection method is applied to the active detection apparatus for the discharge defect of the line insulator described in the embodiment 1 of the present application. The method includes the steps described below.

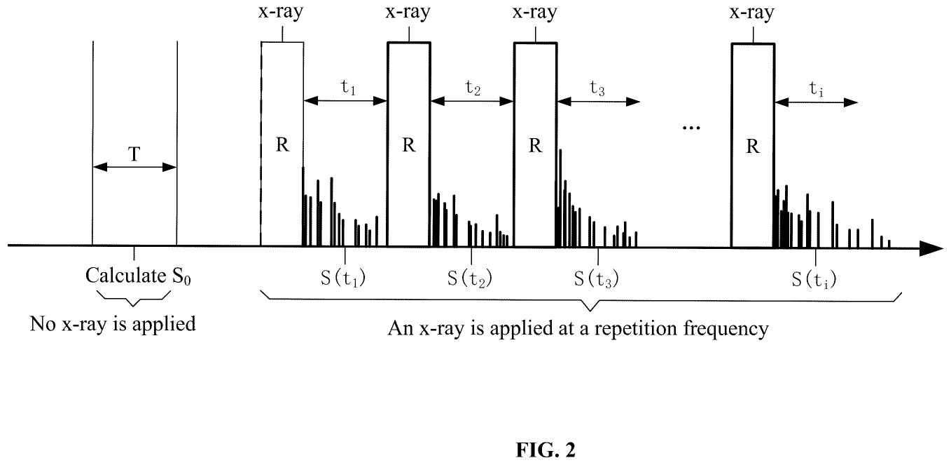

The solar-blind ultraviolet photosensitive detection unit is activated by the execution control unit, a background light pulse is measured when no x-ray is applied, to obtain an average discharge frequency, recorded as no (in units of s⁻¹), within T time. Exemplarily, the rounding of T is as follows:

$$T = \frac{k}{f}$$

where k is an integer greater than zero, and f is a power frequency alternating current period of a power grid;
the execution control unit sets a single pulse x-ray controllable dose R (in units of μSv) of the repetition frequency x-ray pulse light source;
the execution control unit activates the repetition frequency x-ray pulse light source to irradiate a target region of the line insulator, where the x-ray cumulative dose is not higher than 10 mSv;
the execution control unit immediately activates the solar-blind ultraviolet photosensitive detection unit after a pulse output of the repetition frequency x-ray pulse light source is finished, where a detection frequency is kept consistent with an x-ray pulse repetition frequency;
the execution control unit activates the switching quantity counter, and a working time of the switching quantity counter is kept consistent with a working time of the repetition frequency x-ray pulse light source, to obtain a discharge light pulse frequency, recorded as n (in units of s⁻¹), in an x-ray pulse interval time Δt;
the execution control unit activates the ultrasonic distance measurement unit, and a working time of the ultrasonic distance measurement unit is kept consistent with a working time of the repetition frequency x-ray pulse light source, to obtain an ultrasonic distance measurement value L in an x-ray pulse interval time Δt, where the ultrasonic distance measurement value L is recorded as L (in units of: (m));
a startup sequence of the solar-blind ultraviolet photon detection apparatus based on the x-ray source during operation is shown in FIG. 2;
the execution control unit activates the information calculation unit, a working time of the information calculation unit is kept consistent with a working time of the repetition frequency x-ray pulse light source, and a discharge photon excitation intensity S (in units of μSv·s⁻¹·m) at a t moment is calculated according to the following formula:

$$S ( t ) = \frac{R \cdot [ n ( t ) - {n}_{0} ]}{tan θ \cdot L ( t )}$$

in the formula, n(t) is a x-ray discharge light pulse frequency at the t moment, no is an average discharge frequency of the background light pulse within the T time when no x-ray is applied, L(t) is an ultrasonic distance measurement value at the t moment, R is a single pulse x-ray controllable dose of the repetition frequency x-ray pulse light source, and θ is an effective detection angle of the solar-blind ultraviolet photosensitive detection unit.

In some embodiments, the graded evaluation result provided by the information calculation unit includes normal, concern, tracking, early warning, and alarm.

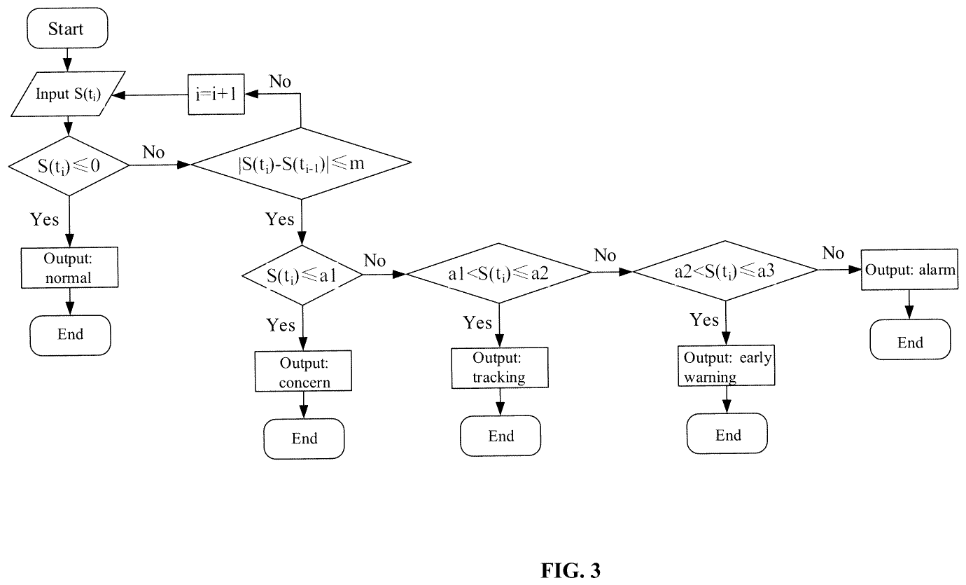

As shown in FIG. 3, the information calculation unit provides the graded evaluation result according to the following judgment logic based on the calculation result of the discharge photon excitation intensity S:
an effective check value m is set;
data S(tᵢ) is input, and if S(tᵢ)≤0, then the graded evaluation result is output as normal;
if S(tᵢ)>0, checking whether the data S(tᵢ) is valid; if |S(tᵢ)−S(tᵢ₋₁)|≤m, then the data S(tᵢ) is considered to be valid for the next evaluation process; and if |S(tᵢ)−S(tᵢ₋₁)|>m, then the data S(tᵢ) is considered to be invalid, the next data is input and the above-described processes are repeated; and
for the valid data where S(tᵢ)>0 and |S(tᵢ)−S(tᵢ₋₁)|≤m, if S(tᵢ)≤a1, then the graded evaluation result is output as concern; if a1<S(tᵢ)≤a2, then the graded evaluation result is output as tracking; if a2<S(tᵢ)≤a3, then the graded evaluation result is output as early warning; and if a3<S(tᵢ), then the graded evaluation result is output as alarm;
where i is a positive integer, and i may be 1, 2, 3 . . . ; m is the effective check value, exemplarily, m=100; and each of a1, a2 and a3 is a state threshold. The values of a1, a2, and a3 may be comprehensively determined based on the insulator type and voltage level. Exemplarily, a1=250, a2=580, a3=1000, in units of μSv·s⁻¹·m.

The following describes method embodiments of the present application to facilitate understanding of the substance and scope of the present application by those skilled in the art.

In some embodiments, a physical detection apparatus is fabricated by using the hardware composition and working principle of the solar-blind ultraviolet photon detection apparatus based on the x-ray source proposed in the present application. The physical detection apparatus is mounted on a platform of the unmanned aerial vehicle (for example, the model of the unmanned aerial vehicle is optionally M300 RTK) to achieve the mounting of the unmanned aerial vehicle. The physical detection apparatus is applied to a 10 kilovolt (kV) distribution line insulator defect detection to ultimately determine that the defective state of the insulator is an early warning state.

The following describes how to apply the principle process of the present application to achieve the above-described effects.
the solar-blind ultraviolet photosensitive detection unit is activated by the execution control unit, the background light pulse is measured when no x-ray is applied, to obtain the average discharge frequency no within the T time (T=100 ms), where no is 210/s;
the execution control unit sets the single pulse x-ray controllable dose R of the repetition frequency x-ray pulse light source, where R=8 μSv, and the pulse width is 2 μs;
the execution control unit activates the repetition frequency x-ray pulse light source to irradiate the target region of the line insulator, where the pulse repetition frequency is 30 Hz, and the x-ray cumulative dose is 3.6 mSv (that is, the total pulse application duration is 15 s);
the execution control unit immediately activates the solar-blind ultraviolet photosensitive detection unit after the pulse output of the repetition frequency x-ray pulse light source is finished, where the detection frequency is kept consistent with the x-ray pulse repetition frequency;
the execution control unit activates the switching quantity counter, and the working time of the switching quantity counter is kept consistent with the working time of the repetition frequency x-ray pulse light source, to obtain the discharge light pulse frequency n in the x-ray pulse interval time Δt, where Δt=33.331 ms, and n ranges from 420 s⁻¹ to 480 s⁻¹;
the execution control unit activates the ultrasonic distance measurement unit, and the working time of the ultrasonic distance measurement unit is kept consistent with the working time of the repetition frequency x-ray pulse light source, to obtain an ultrasonic distance measurement value L in an x-ray pulse interval time Δt, where L=3.1 m to 3.3 m;
the execution control unit activates the information calculation unit, the working time of the information calculation unit is kept consistent with the working time of the repetition frequency x-ray pulse light source, and the discharge photon excitation intensity S (in units of μSv·s⁻¹·m) at the t moment is calculated according to the following formula. In the following formula, an example in which θ=30°, L=3.2, n=433, n₀=210 are used,

$$S ( t ) = \frac{R \cdot [ n ( t ) - {n}_{0} ]}{tan θ \cdot L ( t )} = \frac{R \cdot [ 433 - 210 ]}{tan {30}^{°} \cdot 3.2} = 961.04 μ Sv \cdot {s}^{- 1} \cdot m$$

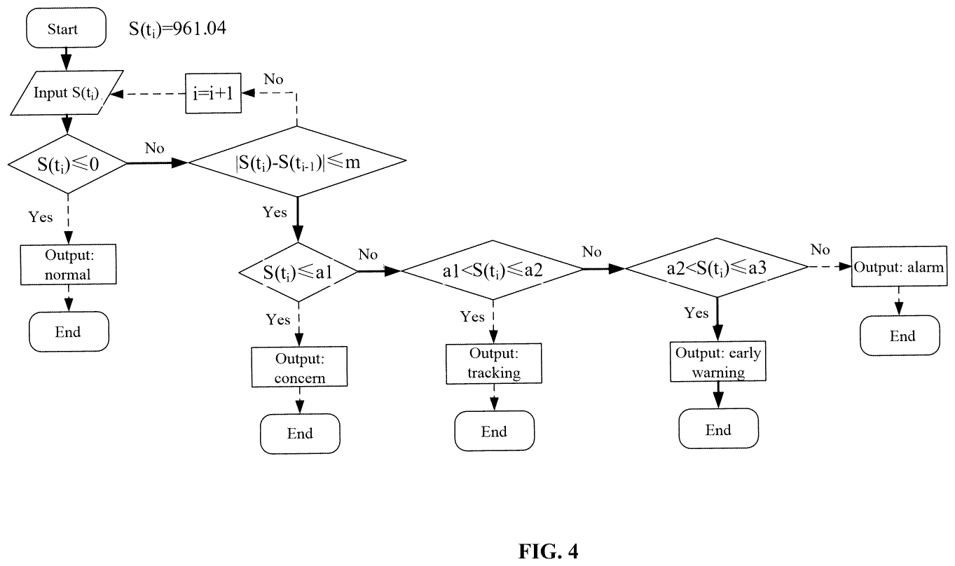

the information calculation unit determines the graded evaluation result as early warning according to the calculation result, that is, a2<S≤a3 (a2=580 and a3=1000 are used as an example), of the discharge photon excitation intensity S and the determination logic (as shown in FIG. 4), this indicates that the discharge state of the measured line insulator is early warning.

In some embodiments, the present application further provides a line insulator discharge defect active detection system. The system includes the active detection apparatus for the discharge defect of the line insulator and the active detection method for the discharge defect of the line insulator. In this system, a passive discharge detection is transformed into an active discharge detection by using the principle of a short-wave light source to reduce the discharge electric field threshold, so that the discharge detection time is shortened, and the discharge activity within the detection period is improved. Moreover, the rapid, accurate, and active detection of various line insulators is achieved by means of the unmanned aerial vehicle, thereby improving the detection and maintenance efficiency of the line external insulation.

Compared with conventional ultrasonic detection, infrared imaging, and ultraviolet imaging detection technologies, the active detection apparatus for the discharge defect of the line insulator and the active detection method for the discharge defect of the line insulator proposed in the present application have the following significant advantages.
(1) A system composed of the active detection apparatus for the discharge defect of the line insulator and its related detection method is mounted on the unmanned aerial vehicle so that the large-area power line can be quickly covered, the detection efficiency is significantly improved, and the tower-by-tower detection is achieved.
(2) The x-ray pulse light source is used for active irradiation, the traditional passive discharge detection is transformed into the active discharge detection, so that the defect can be effectively stimulated to generate the stable discharge in a short time, the detection waiting time is shortened, and the detection efficiency is improved.
(3) The discharge electric field threshold is reduced through the ultraviolet light source, thereby overcoming limitations from the atmospheric environment and the operating voltage.

What is claimed is:

1. An active detection apparatus for a discharge defect of a line insulator, comprising:
a repetition frequency x-ray pulse light source, a solar-blind ultraviolet photosensitive detection unit, a switching quantity counter, an ultrasonic distance measurement unit, an information calculation unit and an execution control unit, wherein,
the execution control unit is connected to each of the repetition frequency x-ray pulse light source, the solar-blind ultraviolet photosensitive detection unit, the switching quantity counter, the ultrasonic distance measurement unit and the information calculation unit, and the execution control unit is configured to control at least one of an operation start and end and an output parameter of the repetition frequency x-ray pulse light source, at least one of an operation start and end and an output parameter of the solar-blind ultraviolet photosensitive detection unit, at least one of an operation start and end and an output parameter of the switching quantity counter, at least one of an operation start and end and an output parameter of the ultrasonic distance measurement unit, and at least one of an operation start and end and an output parameter of the information calculation unit; and
the repetition frequency x-ray pulse light source is configured to generate an x-ray light pulse with a repetition frequency, the ultrasonic distance measurement unit is configured to obtain a distance between the solar-blind ultraviolet photosensitive detection unit and a measured insulator, the solar-blind ultraviolet photosensitive detection unit, the switching quantity counter and the information calculation unit are connected in sequence, the solar-blind ultraviolet photosensitive detection unit is configured to detect an insulation discharge ultraviolet photon generated after x-ray excitation, the switching quantity counter is configured to count a high-level pulse sequence output by the solar-blind ultraviolet photosensitive detection unit, and the information calculation unit is configured to process information output by the switching quantity counter and provide a state determination result of the measured insulator.

2. The active detection apparatus for a discharge defect of a line insulator of claim 1, wherein an irradiation angle of the repetition frequency x-ray pulse light source is not less than 15°, a central wavelength range is 0.5 nm to 10 nm, a controllable dose range of a single pulse x-ray is 5 μSv to 15 μSv, a controllable range of pulse half-peak time is 0.5 μs to 5 μs, and a light pulse repetition frequency is adjustable within 10 Hz to 50 Hz.

3. The active detection apparatus for a discharge defect of a line insulator of claim 1, wherein a response wavelength range of the solar-blind ultraviolet photosensitive detection unit is 240 nm to 280 nm, light quantum efficiency within a solar-blind waveband is not less than 15%, light pulse response time is less than 200 ns, an effective detection angle θ at least ranges from −30° to +30°, and a photoelectric gain is not less than 60 dB.

4. The active detection apparatus for a discharge defect of a line insulator of claim 1, wherein the solar-blind ultraviolet photosensitive detection unit is configured to output a high-level square wave pulse signal after receiving a photon signal, and a pulse width is less than 200 ns.

5. The active detection apparatus for a discharge defect of a line insulator of claim 1, wherein the execution control unit is configured to control the operation start and end and the output parameter of the repetition frequency x-ray pulse light source, the operation start and end of the solar-blind ultraviolet photosensitive detection unit, the operation start and end and the output parameter of the switching quantity counter, and the operation start and end of the information calculation unit.

6. An active detection method for a discharge defect of a line insulator, applied to the active detection apparatus for a discharge defect of a line insulator of claim 1, comprising:
activating, by the execution control unit, the solar-blind ultraviolet photosensitive detection unit, and measuring a background light pulse when no x-ray is applied, to obtain an average discharge frequency, recorded as no, within T time;
setting, by the execution control unit, a single pulse x-ray controllable dose R of the repetition frequency x-ray pulse light source;
activating, by the execution control unit, the repetition frequency x-ray pulse light source to irradiate a target region of a measured line insulator;
immediately activating, by the execution control unit, the solar-blind ultraviolet photosensitive detection unit after a pulse output of the repetition frequency x-ray pulse light source is finished, wherein a detection frequency is kept consistent with an x-ray pulse repetition frequency;
activating, by the execution control unit, the switching quantity counter, and keeping a working time of the switching quantity counter consistent with a working time of the repetition frequency x-ray pulse light source, to obtain a discharge light pulse frequency, recorded as n, in an x-ray pulse interval time Δt;
activating, by the execution control unit, the ultrasonic distance measurement unit, and keeping a working time of the ultrasonic distance measurement unit consistent with the working time of the repetition frequency x-ray pulse light source, to obtain an ultrasonic distance measurement value L in the x-ray pulse interval time Δt; and
activating, by the execution control unit, the information calculation unit, keeping a working time of the information calculation unit consistent with the working time of the repetition frequency x-ray pulse light source, calculating a discharge photon excitation intensity S at a t moment, and providing, by the information calculation unit, a graded evaluation result according to a calculation result of the discharge photon excitation intensity S, to obtain a discharge state of the measured line insulator.

7. The active detection method for a discharge defect of a line insulator of claim 6, wherein when the repetition frequency x-ray pulse light source is activated by the execution control unit to irradiate the target region of the measured line insulator, an x-ray cumulative dose is not higher than 10 mSv.

8. The active detection method for a discharge defect of a line insulator of claim 6, wherein,
the discharge photon excitation intensity S at the t moment is calculated through following formula:
$$S ( t ) = \frac{R \cdot [ n ( t ) - {n}_{0} ]}{tan θ \cdot L ( t )}$$
in the formula, n(t) is an x-ray discharge light pulse frequency at the t moment, no is the average discharge frequency of the background light pulse within the T time when no x-ray is applied, L(t) is an ultrasonic distance measurement value at the t moment, R is the single pulse x-ray controllable dose of the repetition frequency x-ray pulse light source, and θ is an effective detection angle of the solar-blind ultraviolet photosensitive detection unit.

9. The active detection method for a discharge defect of a line insulator of claim 6, wherein the graded evaluation result provided by the information calculation unit comprises normal, concern, tracking, early warning and alarm.

10. The active detection method for a discharge defect of a line insulator of claim 8, wherein providing, by the information calculation unit, the graded evaluation result according to the calculation result of the discharge photon excitation intensity S comprises:
setting an effective check value m;
inputting data S(tᵢ), and outputting, in response to determining that S(tᵢ)≤0, the graded evaluation result as normal;
checking, in response to determining that S(tᵢ)>0, whether the data S(tᵢ) is valid, confirming, in response to determining that |S(tᵢ)−S(tᵢ₋₁)|≤m, that the data S(tᵢ) is valid for a next evaluation process; and
outputting, in response to determining that S(tᵢ)≤a1, the graded evaluation result as concern;
outputting, in response to determining that a1<S(tᵢ)≤a2, the graded evaluation result as tracking; outputting, in response to determining that a2<S(tᵢ)≤a3, the graded evaluation result as early warning; and outputting, in response to determining that a3<S(tᵢ), the graded evaluation result as alarm;
wherein i is a positive integer, each of a1, a2 and a3 is a state threshold.

11. The active detection method for a discharge defect of a line insulator of claim 9, wherein providing, by the information calculation unit, the graded evaluation result according to the calculation result of the discharge photon excitation intensity S comprises:
setting an effective check value m;
inputting data S(tᵢ), and outputting, in response to determining that S(tᵢ)≤0, the graded evaluation result as normal;
checking, in response to determining that S(tᵢ)>0, whether the data S(tᵢ) is valid, confirming, in response to determining that |S(tᵢ)−S(tᵢ₋₁)|≤m, that the data S(tᵢ) is valid for a next evaluation process; and
outputting, in response to determining that S(tᵢ)≤a1, the graded evaluation result as concern;
outputting, in response to determining that a1<S(tᵢ)≤a2, the graded evaluation result as tracking; outputting, in response to determining that a2<S(tᵢ)≤a3, the graded evaluation result as early warning; and outputting, in response to determining that a3<S(tᵢ), the graded evaluation result as alarm;
wherein i is a positive integer, each of a1, a2 and a3 is a state threshold.

12. The active detection method for a discharge defect of a line insulator of claim 6, wherein an irradiation angle of the repetition frequency x-ray pulse light source is not less than 15°, a central wavelength range is 0.5 nm to 10 nm, a controllable dose range of a single pulse x-ray is 5 μSv to 15 μSv, a controllable range of pulse half-peak time is 0.5 μs to 5 μs, and a light pulse repetition frequency is adjustable within 10 Hz to 50 Hz.

13. The active detection method for a discharge defect of a line insulator of claim 6, wherein a response wavelength range of the solar-blind ultraviolet photosensitive detection unit is 240 nm to 280 nm, light quantum efficiency within a solar-blind waveband is not less than 15%, light pulse response time is less than 200 ns, an effective detection angle θ at least ranges from −30° to +30°, and a photoelectric gain is not less than 60 dB.

14. The active detection method for a discharge defect of a line insulator of claim 6, wherein the solar-blind ultraviolet photosensitive detection unit is configured to output a high-level square wave pulse signal after receiving a photon signal, and a pulse width is less than 200 ns.

15. The active detection method for a discharge defect of a line insulator of claim 6, wherein the execution control unit is configured to control the operation start and end and the output parameter of the repetition frequency x-ray pulse light source, the operation start and end of the solar-blind ultraviolet photosensitive detection unit, the operation start and end and the output parameter of the switching quantity counter, and the operation start and end of the information calculation unit.
